(19) United States
(12) Patent Application Publication
(10) Pub. No.: US 2007/0089903 A1
(43) Pub. Date: Apr. 26, 2007

(54) PRINTED CIRCUIT BOARD

(75) Inventor: Ya-Ling Huang, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,411

(22) Filed: Aug. 4, 2006

(30) Foreign Application Priority Data
Oct. 24, 2005 (CN) 200510100596.3

(51) Int. Cl. H01R 12/04; H05K 1/11

(52) U.S. Cl. 174/262

(57) ABSTRACT

A printed circuit board includes a reference layer, a through hole defined in the reference layer, and a plurality of insulating areas are defined in the reference layer around the through hole. The copper around the through hole is separated by the insulating areas and forms a plurality of copper strips. The metal surface area around the through hole available for heat dissipation is reduced to slow down heat distribution. Defect formation is thus reduced when the PCB is in a reflow process.

### FIELD OF THE INVENTION

The present invention relates to a printed circuit board.

### DESCRIPTION OF RELATED ART

Multilayer printed circuit boards (PCBs) are commonly used in electronic devices to connect electronic components such as integrated circuits to one another. A typical multilayer PCB includes many layers of copper, with each layer of copper separated by a dielectric material. Generally, several of the copper layers are used to provide a reference voltage plane or ground plane.

Referring to FIG. 2, a reference plane of a printed circuit board is provided. The printed circuit board 40 includes a reference layer 41, and a through hole 34. A component is mounted on the PCB 40 by inserting a lead through the through hole 34 in the PCB 40 and then soldering the lead in place on the opposite side of the PCB 40 during a reflow process. The lead of the component is electrically connected to the reference plane. The reference plane of the printed circuit board distributes heat quickly due to a large surface area of copper. However, rapid heat dissipation leads to defect formation in the soldering process.

It is therefore apparent that a need exits to provide a PCB that can reduce defect formation when the PCB is in the reflow process.

### SUMMARY OF THE INVENTION

An exemplary printed circuit board includes a reference layer, a through hole defined in the reference layer, and a plurality of insulating areas are defined in the reference layer around the through hole. The copper around the through hole is separated by the insulating areas and forms a plurality of copper strips. The metal area around the through hole available for heat dissipation is reduced to slow down heat distribution. Thus, defect formation is reduced when the PCB is in the reflow process.

Other advantages and novel features will become more apparent from the following detailed description when taken in conjunction with the accompanying drawings, in which:

### BRIEF DESCRIPTION OF THE DRAWINGS

FIG. 1 is a plan view of a reference plane of a printed circuit board (PCB) in accordance with a preferred embodiment of the preset invention; and

FIGS. 2 is a plan view of a reference plane of a conventional PCB with a through hole defined therein.

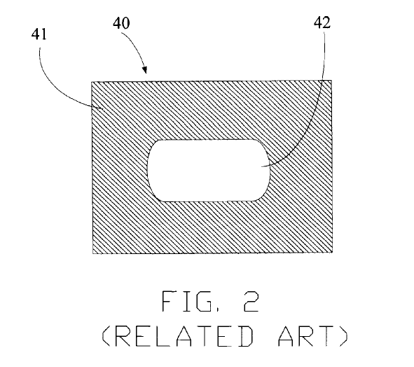

### DETAILED DESCRIPTION OF THE INVENTION

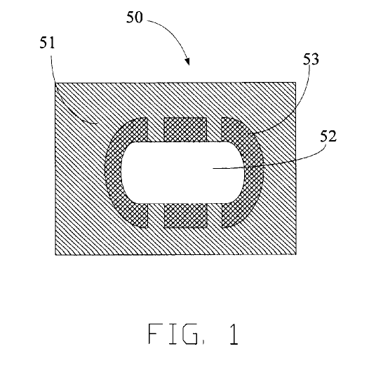

Referring to FIG. 1, a reference plane of a printed circuit board (PCB) according to a preferred embodiment of the present invention is provided. The PCB 50 includes a reference layer 51, a through hole 52, and a plurality of etched insulating areas 53 surrounding the through hole 52. The through hole 52 is generally ellipse shaped. The reference plane 51 is a solid copper layer. The copper around the through hole 52 is separated by the insulating areas 53 and forms a plurality of copper strips. The reference layer 51 is electrically connected to the components inserted in the through hole 52 by the copper strips. Preferably, a width of the strips is approximately 14 mils, and a width of the insulating areas is approximately 15 mils.

In this embodiment the metal area around the through hole 52 available for heat dissipation is much smaller than on conventional PCBs, to slow down heat distribution. Defect formation is thus reduced when the PCB is in a reflow process.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A printed circuit board (PCB) comprising:
a reference layer;
a through hole for a lead of a component inserting therethrough defined in the reference layer; and
a plurality of insulating areas defined in the reference layer around the through hole.

2. The PCB as claimed in claim 1, wherein the reference layer is a solid copper layer.

3. The PCB as claimed in claim 2, wherein copper around the though hole is separated by the plurality of insulating areas and forms a plurality of copper strips.

4. The PCB as claimed in claim 3, wherein a width of each of the copper strips is approximately 14 mils.

5. The PCB as claimed in claim 1, wherein a width of each of the insulating areas is approximately 15 mils.

6. The PCB as claimed in claim 1, wherein the through hole has an ellipse shape.

7. A method for making a printed circuit board (PCB) comprising steps of:
providng a reference layer with a through hole for a lead of a component inserting therein; and
etching a plurality of insulating areas on the reference layer around the through hole for a reduced area of heat dissipation.

8. The method as claimed in claim 7, wherein the reference layer is a solid copper layer.

9. The method as claimed in claim 8, wherein copper around the though hole is separated by the plurality of insulating areas and forms a plurality of copper strips.

10. The PCB as claimed in claim 7, wherein the through hole has an ellipse shape.
